(19) United States
(12) Patent Application Publication
(10) Pub. No.: US 2020/0413554 A1
(43) Pub. Date: Dec. 31, 2020

(54) INSULATING FLEXIBLE MEMBRANES FOR HIGH VOLTAGE MODULES

(71) Applicant: FORD GLOBAL TECHNOLOGIES, LLC, Dearborn, MI (US)

(72) Inventors: John Marshall PENNEY, Livonia, MI (US); Mark Andrew COLDREN, Westland, MI (US); Doug G. HUGHES, South Lyon, MI (US); Patrick Daniel MAGUIRE, Ann Arbor, MI (US)

(21) Appl. No.: 16/452,801

(22) Filed: Jun. 26, 2019

(51) Int. Cl. H05K 5/02; H05K 1/02; H01B 3/44; B60L 50/50; H05K 7/14

(52) U.S. Cl. CPC H05K 5/0217; H05K 1/0254; H05K 7/1427; B60L 50/50; H01B 3/441

(57) ABSTRACT

This disclosure details exemplary insulating flexible membranes for use with vehicle high voltage modules. The high voltage modules may include any module that is adapted for supporting electric propulsion within the vehicle. The insulating flexible membranes may be attached to an exterior of a housing, to an interior of the housing, or may be disposed about a high voltage component housed inside the module. The insulating flexible membranes of this disclosure are configured to distort to prevent access to damaged high voltage components of the high voltage modules.

### TECHNICAL FIELD

This disclosure relates to vehicle high voltage modules, and more particularly to insulating flexible membranes for high voltage modules.

### BACKGROUND

Electrified vehicles (e.g., hybrid electric vehicles (HEVs), plug-in hybrid electric vehicles (PHEVs), battery electric vehicles (BEVs), etc.) are equipped with a plurality of high voltage modules that support electric propulsion of the vehicle. One example of a high voltage module suited for this purpose is the traction battery pack. A housing or enclosure of each high voltage module houses the high voltage circuitry necessary for achieving the electric propulsion.

### SUMMARY

A vehicle high voltage module according to an exemplary aspect of the present disclosure includes, among other things, a housing, a high voltage component housed inside the housing, and an insulating flexible membrane affixed to a conductive surface of the housing or positioned around the high voltage component.

In a further non-limiting embodiment of the foregoing vehicle high voltage module, the vehicle high voltage module is a traction battery pack, an AC compressor, or a DC/DC converter.

In a further non-limiting embodiment of either of the foregoing vehicle high voltage modules, the high voltage component is a battery array.

In a further non-limiting embodiment of any of the foregoing vehicle high voltage modules, the high voltage component is a circuit board.

In a further non-limiting embodiment of any of the foregoing vehicle high voltage modules, the insulating flexible membrane encapsulates the circuit board.

In a further non-limiting embodiment of any of the foregoing vehicle high voltage modules, the conductive surface is part of an interior surface of the housing.

In a further non-limiting embodiment of any of the foregoing vehicle high voltage modules, the conductive surface is part of an exterior surface of the housing.

In a further non-limiting embodiment of any of the foregoing vehicle high voltage modules, the insulating flexible membrane is adhesively bonded to the conductive surface by an adhesive.

In a further non-limiting embodiment of any of the foregoing vehicle high voltage modules, the insulating flexible membrane is mechanically fastened to the conductive surface by a bolt or a screw.

In a further non-limiting embodiment of any of the foregoing vehicle high voltage modules, the insulating flexible membrane is an over-molded section of the housing.

In a further non-limiting embodiment of any of the foregoing vehicle high voltage modules, the insulating flexible membrane is flexible and non-conductive.

In a further non-limiting embodiment of any of the foregoing vehicle high voltage modules, the insulating flexible membrane is constructed of high density polyethylene (HDPE).

In a further non-limiting embodiment of any of the foregoing vehicle high voltage modules, the insulating flexible membrane is constructed of thermoplastic olefin (TPO).

In a further non-limiting embodiment of any of the foregoing vehicle high voltage modules, the insulating flexible membrane includes a layer of high tensile material.

In a further non-limiting embodiment of any of the foregoing vehicle high voltage modules, the insulating flexible membrane includes an opening configured for receiving a fastener.

An electrified vehicle according to another exemplary aspect of the present disclosure includes, among other things, a high voltage module and an insulating flexible membrane affixed to a conductive surface of a housing of the high voltage module.

In a further non-limiting embodiment of the foregoing electrified vehicle, the high voltage module is a traction battery pack, an AC compressor, or a DC/DC converter.

In a further non-limiting embodiment of either of the foregoing The electrified vehicles, the insulating flexible membrane is adhesively bonded to the conductive surface by an adhesive.

In a further non-limiting embodiment of any of the foregoing electrified vehicles, the insulating flexible membrane is constructed of high density polyethylene (HDPE) or thermoplastic olefin (TPO).

In a further non-limiting embodiment of any of the foregoing electrified vehicles, a high voltage component is housed inside the housing. The insulating flexible membrane establishes a flexible barrier over or around the high voltage component.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

The various features and advantages of this disclosure will become apparent to those skilled in the art from the following detailed description. The drawings that accompany the detailed description can be briefly described as follows.

### BRIEF DESCRIPTION OF THE DRAWINGS

FIG. 1 schematically illustrates a powertrain of an electrified vehicle.

FIG. 2 schematically illustrates an exemplary high voltage module of an electrified vehicle powertrain.

FIG. 3 illustrates the high voltage module of FIG. 2 and depicts an insulating flexible membrane of the high voltage module.

FIG. 4 illustrates an insulating flexible membrane adhesively bonded to a high voltage module.

FIG. 5 illustrates an insulating flexible membrane mechanically fastened to a high voltage module.

FIG. 6 illustrates an insulating flexible membrane disposed around a high voltage component of a high voltage module.

FIG. 7 illustrates another exemplary high voltage module.

FIG. 8 is an end view of the high voltage module of FIG. 6 and depicts an insulating flexible membrane of the high voltage module.

FIG. 9 illustrates yet another exemplary high voltage module.

FIG. 10 is a top view of the high voltage module of FIG. 9 and depicts an insulating flexible membrane of the high voltage module.

### DETAILED DESCRIPTION

This disclosure details exemplary insulating flexible membranes for use with vehicle high voltage modules. The high voltage modules may include any module that is adapted for supporting electric propulsion within the vehicle. The insulating flexible membranes may be attached to an exterior of a housing, to an interior of the housing, or may be disposed about a high voltage component housed inside the module. The insulating flexible membranes of this disclosure are configured to distort to prevent access to damaged high voltage components of the high voltage modules. These and other features are discussed in greater detail in the following paragraphs of this detailed description.

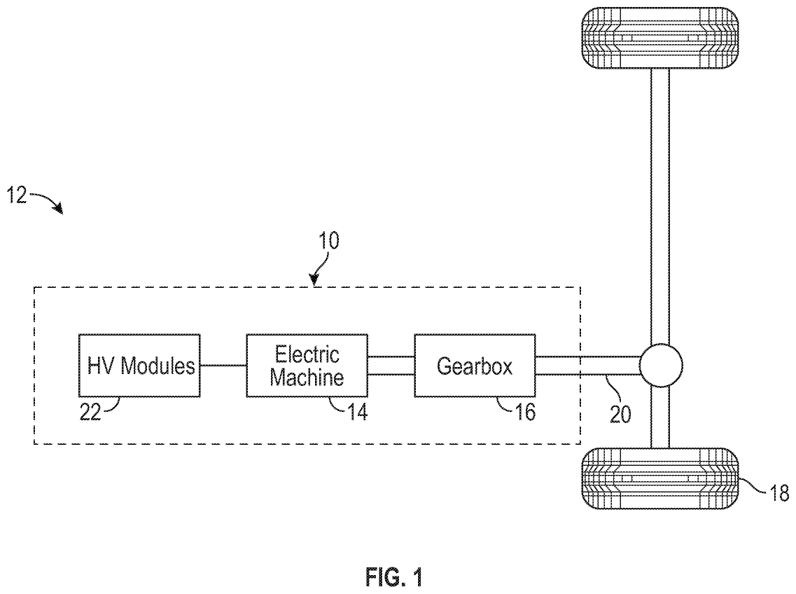

FIG. 1 schematically illustrates a powertrain 10 of an electrified vehicle 12. In an embodiment, the electrified vehicle 12 is a battery electric vehicle (BEV). In another embodiment, the electrified vehicle 12 is a hybrid electric vehicle (HEV) or a plug-in hybrid electric vehicle (PHEV). Therefore, although not shown in this embodiment, the electrified vehicle 12 could be equipped with an internal combustion engine that can be employed either alone or in combination with other energy sources to propel the electrified vehicle 12.

The electrified vehicle 12 may be propelled solely through electric power, such as by an electric machine 14, without any assistance from an internal combustion engine. The electric machine 14 may operate as an electric motor, an electric generator, or both. The electric machine 14 receives electrical power and provides a rotational output torque. The electric machine 14 may be connected to a gearbox 16 for adjusting the output torque and speed of the electric machine 14 by a predetermined gear ratio. The gearbox 16 is operably connected to a set of drive wheels 18 by an output shaft 20.

A plurality of high voltage modules 22 enable the electric propulsion of the electrified vehicle 12. The high voltage modules 22 may be any electric drive powertrain component that supports electric propulsion of the electrified vehicle 12. In this disclosure, the term “high voltage” denotes a component that operates at a voltage of greater than 30 volts alternating current (AC) or greater than 60 volts direct current (DC). Exemplary high voltage modules 22 of the electrified vehicle 12 may include, but are not limited to, a high voltage traction battery pack, a high voltage charger (sometimes referred to as an on-board charger), a motor controller (sometimes referred to as an ISC inverter), a DC/DC converter, an auxiliary water pump, an electric heater, an AC compressor, a DC/AC Inverter, a junction box, a power distribution unit, a positive temperature coefficient heater, an electric machine, and an on-board generator module.

The powertrain 10 depicted by FIG. 1 is highly schematic and is not intended to limit this disclosure. Various additional components could alternatively or additionally be employed by the powertrain 10 of the electrified vehicle 12 within the scope of this disclosure.

Depending on their vehicle mounting locations, the high voltage modules 22 of the powertrain 10 may be susceptible to damage during vehicle impact events, thereby potentially exposing components that have relatively high voltage potentials and energy. Novel insulating flexible membranes for preventing access to high voltage components of the high voltage modules 22 are therefore proposed in this disclosure.

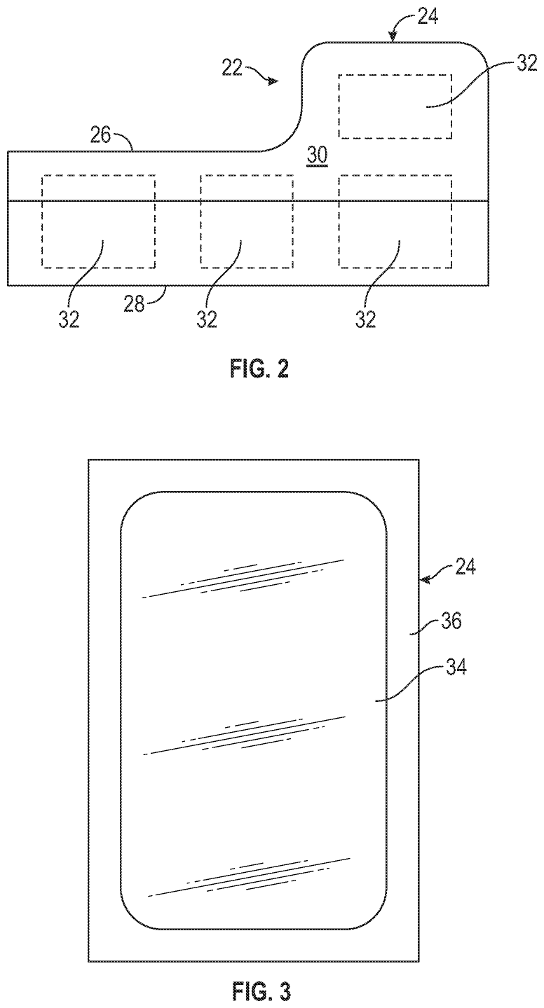

FIGS. 2 and 3 illustrate an exemplary high voltage module 22 that may be employed within a vehicle, such as the electrified vehicle 12 of FIG. 1. In this embodiment, the high voltage module 22 is a high voltage traction battery pack capable of outputting electrical power to operate the electric machine 14 and/or other electrical loads of the electrified vehicle 12.

The high voltage module 22 may include a housing 24. In an embodiment, the housing 24 includes a first housing section 26 (e.g., a cover) and a second housing section 28 (e.g., a tray) that cooperate to establish an interior 30. The first housing section 26 and the second housing section 28 may be secured together in any known manner in order to construct the housing 24. The housing 24 may be constructed of metallic materials, polymer-based materials, textile materials, or any combination of these materials. The housing 24 of the high voltage module 22 may include any size, shape, and configuration and is therefore not limited to the exact configuration shown in FIGS. 2-3.

One or more high voltage components 32 may be housed within the interior 30. In this embodiment, the high voltage components 32 may include battery arrays (i.e., groupings of battery cells or other energy storage devices) and/or various battery electronic components (e.g., control modules, wiring, etc.).

The high voltage module 22 may additionally include one or more insulating flexible membranes 34 (see FIG. 3). The insulating flexible membrane 34 may be provided to cover a majority of the housing 24 or could alternatively be provided at only discrete portions of the housing 24 that correspond to regions of the high voltage module 22 where the high voltage components 32 are housed. The insulating flexible membrane 34 may be connected to a conductive surface 36 of the housing 24. The conductive surface 36 could be part of the first housing section 26, the second housing section 28, or both. In addition, the conductive surface 36 could be located at an exterior surface of the housing 24, an interior surface of the housing 24, or both.

In an embodiment, shown in FIG. 3, the insulating flexible membrane 34 is integrally molded into at least a portion of the conductive surface 36 of the housing 24. The insulating flexible membrane 34 may be over-molded into place relative to the conductive surface 36, for example.

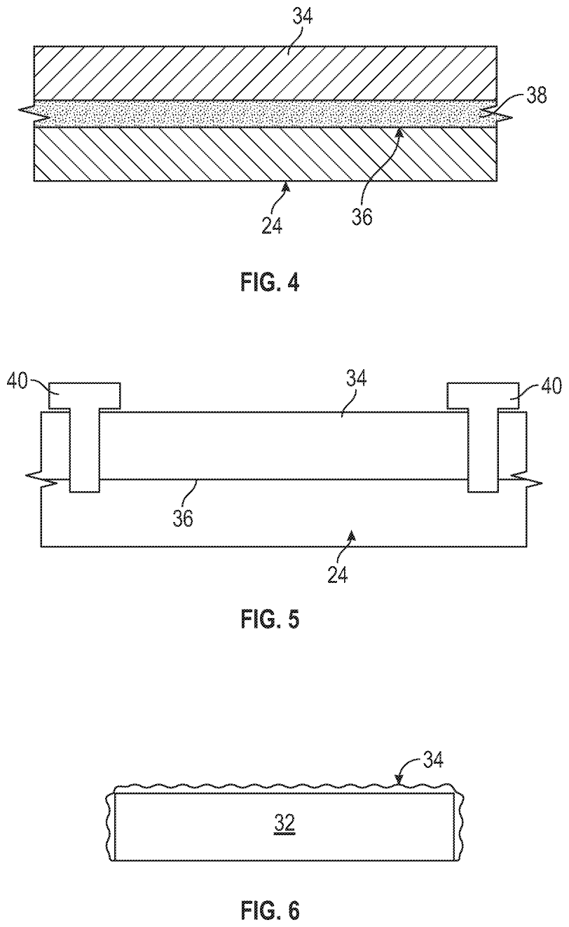

In another embodiment, shown in FIG. 4, the insulating flexible membrane 34 is adhesively bonded to the conductive surface 36 of the housing 24 by an adhesive 38. The adhesive 38 effectively affixes the insulating flexible membrane 34 to the conductive surface 36 similar to the manner a sticker is secured to a surface. The adhesive 38 may be a bioadhesive, a rubber adhesive, an acrylic or acrylic blend adhesive, a glue, or any other suitable adhesive. The type of adhesive that is used to secure the insulating flexible membrane 34 to the conductive surface 36 of the housing 24 may depend upon the material make-ups of both the insulating flexible membrane 34 and the housing 24, among various other design criteria. FIG. 4 is not shown to scale, and certain aspects may be enlarged to better illustrate various concepts of this embodiment.

In another embodiment, shown in FIG. 5, the insulating flexible membrane 34 is fastened to the conductive surface 36 of the housing 24 by one or more insulating fasteners 40. The insulating fasteners 40 may be bolts, screws, push pins, snap locks, clips, rivets, or any other suitable fastener. Alternatively, a non-insulating fastener could be used if secured from inside-out such that the conductive tips remain buried within the insulating flexible membrane 34.

In yet another embodiment, shown in FIG. 6, the insulating flexible membrane 34 may be positioned around a high voltage component 32 of the high voltage module 22 such that the insulating flexible membrane 34 substantially encapsulates the high voltage component 32. The insulating flexible membrane 34 may be heat or vacuum shrunk to more tightly conform to the high voltage component 32. The high voltage component 32 may be a circuit board or any other high voltage component.

The insulating flexible membrane 34 is designed to bend, stretch, or otherwise distort in situations where the housing 24 of the high voltage module 22 is fractured, torn, bent, buckled, twisted, or otherwise damaged. The insulating flexible membrane 34 may maintain the housing 24 intact and acts as a bridge to substantially prevent damaged portions from becoming displaced from the housing 24. By distorting, the insulating flexible membrane 34 remains in place over the high voltage components 32, thereby preventing finger or probe access to the high voltage circuitry of the high voltage module 22.

In order to achieve the above objectives, the insulating flexible membrane 34 may be constructed of a relatively high strength yet resilient and non-conductive material. Exemplary high strength, resilient, and non-conductive materials include, but are not limited to, high density polyethylene (HDPE), thermoplastic olefin (TPO), and other similar materials.

In an embodiment, the insulating flexible membrane 34 may optionally include a layer of high tensile material such as a bonded fiberglass, a molded-in layer of a preimpregnated polymer or thermoplastic organo sheet, or a reinforced polymer layer. If needed, the layer of high tensile material can enhance the durability of the insulating flexible membrane 34 and prevent it from stretching substantially while still allowing some degree of flexure and integrity.

The exemplary insulating flexible membranes 34 described above are detailed in the context of a high voltage traction battery pack for an electrified vehicle. However, this disclosure is not limited to use with battery packs. Other vehicle high voltage modules could also benefit from the insulating flexible membrane designs described herein. The term “high voltage module” is intended to include any module that houses high voltage circuitry adapted for supporting electric propulsion of the electrified vehicle.

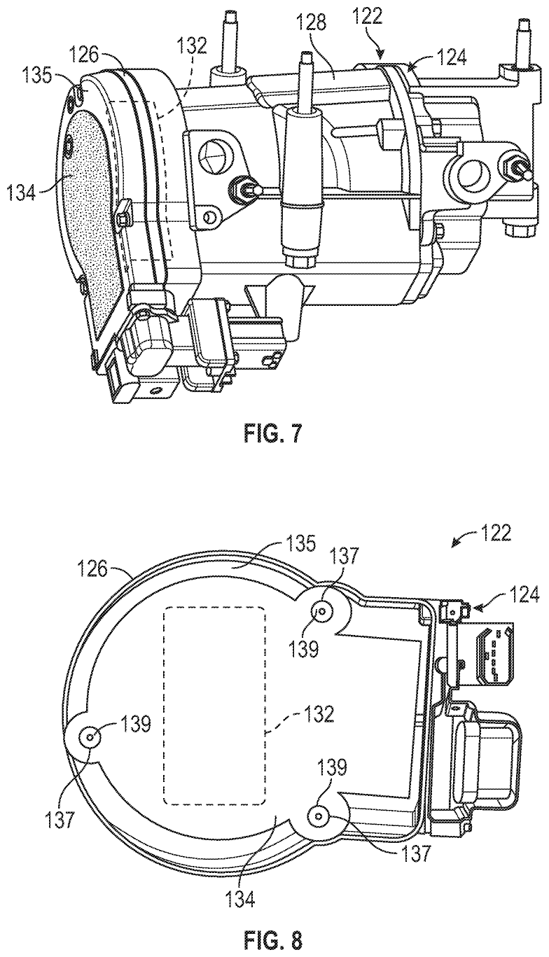

In this regard, another exemplary high voltage module 122 is shown in FIGS. 7-8. In this embodiment, the high voltage module 122 is an AC compressor.

The high voltage module 122 includes a housing 124. In an embodiment, the housing 124 includes a first housing section 126 (e.g., a cover) and a second housing section 128 (e.g., a main housing section). One or more high voltage components 132 may be housed behind the first housing section 126.

An insulating flexible membrane 134 may be secured to an exterior surface 135 (e.g., a conductive surface) of the first housing section 126. In another embodiment, the insulating flexible membrane 134 is secured inside the first housing section 126. In an embodiment, the insulating flexible membrane 134 includes one or more openings 137 (three openings shown as a non-limiting example). The openings 137 are configured to receive fasteners 139 (e.g., bolts or screws) for mechanically securing the insulating flexible membrane 134 to the first housing section 126.

The insulating flexible membrane 134 is designed to bend, stretch, or otherwise distort in situations where the first housing section 126 of the high voltage module 122 is fractured or otherwise damaged. By stretching and conforming to the distorted shape of the first housing section 126, the insulating flexible membrane 134 remains in place over the high voltage components 132, thereby preventing finger or probe access to the high voltage circuitry of the high voltage module 122.

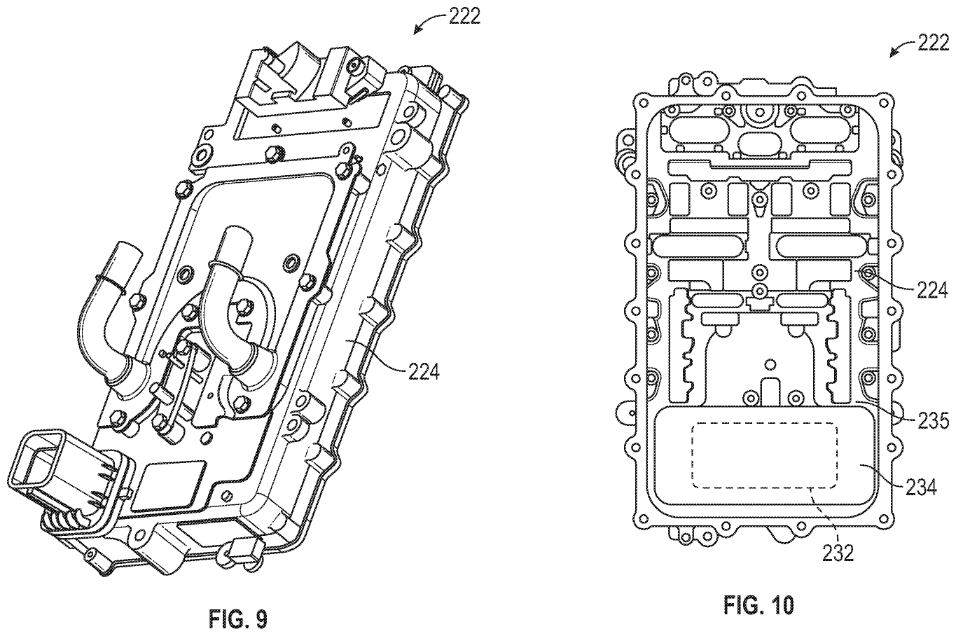

Another exemplary high voltage module 222 is shown in FIGS. 9-10. In this embodiment, the high voltage module 222 is a DC/DC converter.

The high voltage module 222 includes a housing 224. One or more high voltage components 232 (see FIG. 10) may be housed inside the housing 224.

An insulating flexible membrane 234 may be secured to an exterior surface 235 (e.g., a conductive surface) of the housing 224 in the region of the housing 224 that houses the high voltage component 232. In another embodiment, the insulating flexible membrane 234 is secured to an interior surface of the housing 224. The insulating flexible membrane 234 may be affixed to the housing 224 in any of the manners described above (e.g., adhesively bonded, molded-in, fastened, etc.).

The insulating flexible membrane 234 is designed to bend, stretch, or otherwise distort in situations where the housing 224 of the high voltage module 222 is fractured or otherwise damaged. By distorting, the insulating flexible membrane 234 remains in place over the high voltage components 232, thereby preventing finger or probe access to the high voltage circuitry of the high voltage module 222.

The exemplary insulating flexible membranes of this disclosure prevent access to damaged high voltage components, thereby providing internal high voltage circuit protection. The insulating flexible membranes provide a high strength, flexible, and non-conductive barrier that is capable of withstanding a relatively high amount of force.

Although the different non-limiting embodiments are illustrated as having specific components or steps, the embodiments of this disclosure are not limited to those particular combinations. It is possible to use some of the components or features from any of the non-limiting embodiments in combination with features or components from any of the other non-limiting embodiments.

It should be understood that like reference numerals identify corresponding or similar elements throughout the several drawings. It should be understood that although a particular component arrangement is disclosed and illustrated in these exemplary embodiments, other arrangements could also benefit from the teachings of this disclosure.

The foregoing description shall be interpreted as illustrative and not in any limiting sense. A worker of ordinary skill in the art would understand that certain modifications could come within the scope of this disclosure. For these reasons, the following claims should be studied to determine the true scope and content of this disclosure.

1. A vehicle high voltage module, comprising:
a housing;
a high voltage component housed inside the housing; and
an insulating flexible membrane affixed to a conductive surface of the housing or positioned around the high voltage component.

2. The vehicle high voltage module as recited in claim 1, wherein the vehicle high voltage module is a traction battery pack, an AC compressor, or a DC/DC converter.

3. The vehicle high voltage module as recited in claim 1, wherein the high voltage component is a battery array.

4. The vehicle high voltage module as recited in claim 1, wherein the high voltage component is a circuit board, and further wherein the insulating flexible membrane encapsulates the circuit board.

5. (canceled)

6. The vehicle high voltage module as recited in claim 1, wherein the conductive surface is part of an interior surface of the housing.

7. The vehicle high voltage module as recited in claim 1, wherein the conductive surface is part of an exterior surface of the housing and the insulating flexible membrane is affixed to the exterior surface.

8. The vehicle high voltage module as recited in claim 1, wherein the insulating flexible membrane is adhesively bonded to the conductive surface by an adhesive.

9. The vehicle high voltage module as recited in claim 1, wherein the insulating flexible membrane is mechanically fastened to the conductive surface by an insulating fastener.

10. The vehicle high voltage module as recited in claim 1, wherein the insulating flexible membrane is an over-molded portion of the housing.

11. The vehicle high voltage module as recited in claim 1, wherein the insulating flexible membrane is flexible and non-conductive.

12. The vehicle high voltage module as recited in claim 1, wherein the insulating flexible membrane is constructed of high density polyethylene (HDPE).

13. The vehicle high voltage module as recited in claim 1, wherein the insulating flexible membrane is constructed of thermoplastic olefin (TPO).

14. The vehicle high voltage module as recited in claim 1, wherein the insulating flexible membrane includes a layer of high tensile material.

15. The vehicle high voltage module as recited in claim 1, wherein the insulating flexible membrane includes an opening configured for receiving a fastener.

16. An electrified vehicle, comprising:
a high voltage module; and
an insulating flexible membrane affixed to a conductive surface of a housing of the high voltage module.

17. The electrified vehicle as recited in claim 16, wherein the high voltage module is a traction battery pack, an AC compressor, or a DC/DC converter.

18. The electrified vehicle as recited in claim 16, wherein the insulating flexible membrane is adhesively bonded to the conductive surface by an adhesive.

19. The electrified vehicle as recited in claim 16, wherein the insulating flexible membrane is constructed of high density polyethylene (HDPE) or thermoplastic olefin (TPO).

20. The electrified vehicle as recited in claim 16, comprising a high voltage component housed inside the housing, wherein the insulating flexible membrane establishes a flexible barrier over or around the high voltage component.

21. The electrified vehicle as recited in claim 16, wherein the conductive surface is at an exterior surface of the housing, and the insulating flexible membrane is affixed to the conductive surface at the exterior surface.

22. The electrified vehicle as recited in claim 21, wherein the insulating flexible membrane is configured to bend, stretch, or otherwise distort and thereby keep portions of the housing intact during vehicle impact events.

23. The vehicle high voltage module as recited in claim 1, wherein the insulating flexible membrane is a heat or vacuum shrinkable membrane.

24. The vehicle high voltage module as recited in claim 1, wherein the insulating flexible membrane is affixed to an interior surface or an exterior surface of the housing, and further wherein the insulating flexible membrane is configured to bend, stretch, or otherwise distort during vehicle impact events, thereby blocking access to the high voltage component.

25. The vehicle high voltage module as recited in claim 1, wherein the layer of high tensile material includes a bonded fiberglass or a preimpregnated polymer or thermoplastic organo sheet.
